(19) United States
(12) Patent Application Publication
(10) Pub. No.: US 2019/0371956 A1
(43) Pub. Date: Dec. 5, 2019

(54) Avalanche Photodetector with Single Mesa Shape

(71) Applicant: National Central University, Taoyuan City (TW)

(72) Inventor: Jin-Wei Shi, Taoyuan City (TW)

(21) Appl. No.: 15/993,714

(22) Filed: May 31, 2018

(51) Int. Cl. H01L 31/107; H01L 31/0304; H01L 31/0232; H01L 31/0352; H01L 31/0224

(52) U.S. Cl. CPC H01L 31/1075; H01L 31/03046; H01L 31/022408; H01L 31/035281; H01L 31/02327

(57) ABSTRACT

A photodetector is provided. The photodetector is an avalanche photodiode of indium aluminum arsenide (InAlAs). An epitaxial-layers structure with n-side down is used. The strongest electric field of a multiplication layer (M-layer) is coated in inner bottom layers to avoid surface breakdown. An intrinsic layer is thickened; only one absorption layer is used; and a DBR layer is added below an n-type ohmic contact layer. A graded bandgap layer is etched to form a single mesa shape. Through the single mesa shape, all layers are far below breakdown except the M-layer has a particularly high electric field for restraining the electric field. Thus, the present invention changes holes into electrons through p-type-doping the absorption layer; because electrons run fast, carriers is made run fast; and junction capacitance is reduced with surface area increased by depletion layer thickened. Consequently, fast response speed is obtained while sensitivity is effectively improved.

### TECHNICAL FIELD OF THE INVENTION

The present invention relates to an avalanche photodetector; more particularly, to thickening an intrinsic layer (i-layer), using only one absorption layer (p-type doped) and adding a distributed Bragg reflector (DBR) layer below an n-type ohmic contact layer with a mesa shape etched out, where, through the single mesa shape, a multiplication layer (M-layer) obtains a high electric field at the center of the device along with a low electric field at the edge of the device; the electric field of the M-layer is limited; and all layers are far below breakdown except the M-layer has a particularly high electric field.

### DESCRIPTION OF THE RELATED ARTS

To meet the much more demands of the internet of things (IOT) for virtual machines using bit data, traditional copper wires have long been unable to take on the transmission tasks (≥˜100 meters (m)). Optical fiber having transmission bandwidth of no bottom still is bound to be the only hope. Under consideration of market sizes, costs and expected technology developments for different transmission distances, a project group for 400-gigabit Ethernet (GbE) separately worked out interfaces for the transmission distances of 100 m, 500 m, 2 kilometers (km) and 10 km. Therein, the interface of 400 giga-bits per second (Gbps) for 100 m was determined to transmit direct-modulation signals by a vertical cavity surface emitting laser (VCSEL, @850 nm) of 25 Gbps per channel in 100 GbE through a multimode fiber (MMF); yet, the target of 400 Gbps was achieved by multiplying the number of fibers and lasers for four times. For the interface for more than 500 m, a light source of 1310 nm was used for transmission through single-mode fiber (SMF). In the considerations of the project group, a solution could be that the signal velocity for each single light source achieved 50 Gbps or 100 Gbps and then eight or four channels were used (multiple wavelengths in a single fiber or a single wavelength in multiple fibers) to achieve the transmission capacity of 400 Gbps. However, when the speed for single light source in Ethernet reaches more than 25 Gbps, the high-bandwidth photovoltaic device (including the photoelectric conversion in the electro-optical modulating and receiving module of a transmitter module) normally had a smaller optical power output (about 1 milli-watts (mW); −2 to +2 decibels per milliwatt (dBm)). If the technology of wavelength division multiplexing (WDM) was continued to be used, the insertion loss in passive device would make the power budget become the key issue of limiting the maximum transmission capacity. As was revealed in “Design and Performance of High-Speed Avalanche Photodiodes for 100-Gb/s Systems and Beyond” by M. Nada, T. Yoshimatsu, Y. Muramoto, H. Yokoyama, and H. Matsuzaki (IEEE/OSA Journal of Lightwave Technology, vol. 33, no. 5, pp. 984-990, March, 2015.), it was known from the causes of the insertion loss that the receiving end required a sensitivity about −13 dBm. A general receiver of p-i-n photodiode has a sensitivity about more than −10 dBm under the operation of 25 giga-bits per second (Gbit/sec) bandwidth.

In FIG. 5, “Degradation Mode Analysis on Highly Reliable Guarding-Free planar InAlAs Avalanche Photodiodes” by E. Ishimura, E. Yagyu, M. Nakaji, S. Ihara, K. Yoshiara, T. Aoyagi, Y. Tokuda, and T. Ishikawa (IEEE/OSA Journal of Lightwave Technology, vol. 25, pp. 3686-3693, December, 2007.) revealed a cross-section structure of an avalanche photodiode using a multiplication layer (M-layer) of planar indium aluminum arsenide (InAlAs). As shown in the figure, the high field region 3 had a zinc diffusion region to restrain the electric field; but no mesa structure existed and, therefore, the electric field at the edge had poor limitation. The threshold of the breakdown field (>550 kilo-volts per centimeter) might be easily exceeded. When the M-layer was made thin, breakdown might happen at the edge for achieving required operation gain.

FIG. 6 shows the prior art of the cross-section structures of the avalanche photodiodes of 25 Gbit/sec and 50 Gbit/sec developed by NTT Electronic in the last two years. From top to bottom, the structure comprised an N-contact layer 40, an edge-field buffer layer 41, an N-charge layer 42, an InAlAs avalanche layer 43, a P-charge layer 44, an undoped indium gallium arsenide (InGaAs) absorption layer 45, a P-type InGaAs absorption layer 46, a P-contact layer 47, a semi-insulating InP substrate 48 and an anti-reflection layer 49. In the figure, for achieving good field-limitation, the structure quite particularly had the InGaAs M-layer 43 and the N-contact layer 40 deposed near the surface (structure inverted). Consequently, most of the electric field of the InGaAs M-layer 43 would be restrained under the N-contact layer 40. However, for reducing the chance of surface breakdown, the excessive edge-field buffer layer 41 and N-charge layer 42 are required, which might result in impact on device speed. Besides, the inverted structure (p-side down) required the use of P-type InP-based alloy having a wider bandgap. As a result, the ohmic contact might be hard to be produced and the resistance of the whole device is made big. In addition, the structure also sacrificed the field-limitation of the P-type InGaAs absorption layer 46, where the parasitic capacitance of the device might become bigger. Nevertheless, because of the stronger fringe field in the absorption layer, the difficulty of packaging the device was increased (F Nakajima, M. Nada, and T. Yoshimatsu, “High-Speed Avalanche Photodiode and High-Sensitivity Receiver Optical Sub-Assembly for 100-Gb/s Ethernet,” to be published in IEEE/OSA Journal of Lightwave Technology, vol. 33, 2015.) Hence, for restraining the electric field, the M-layer was deposed outside to be exposed in the air. This could cause reliability problem.

From the results of the sensitivity measured under the operations of 25 Gbit/sec and 50 Gbit/sec, it is clearly found that the sensitivity of 25 Gbit/sec and 50 Gbit/sec were approximately −15.5 dBm and −11 dBm. As comparing to the pin-photodetector-based light receiving modules, the responses were increased for about 4 decibels (dB) and 1.5 dB, respectively. As the results showed, following the increase of data rate, the enhancement in the sensitivity of this breakdown photodiode structure would become smaller. This is most likely because that, following the increase in required operation bandwidth, the M-layer was required to be thinned. Yet, this made the dark current abruptly rise to deteriorate the sensitivity.

Under the above concerns, a prior art used a double-mesa structure to achieve the effect of field-limitation of the M-layer. But, because holes run much slower than electronics, holes will be accumulated in intrinsic area to form a field shielding effect of making inner field smaller. Therefore, the discharging speed of carrier became slower to further affect the output power as the device was made much slower in speed. Hence, the prior arts do not fulfill all users' requests on actual use.

### SUMMARY OF THE INVENTION

The main purpose of the present invention is to provide an epitaxial-layers structure with n-side down, where the strongest electric field of an M-layer is coated in inner bottom layers to avoid surface breakdown; a single mesa shape is used to limit the electric field of the M-layer; and all layers are far below breakdown except the M-layer has a particularly high electric field.

Another purpose of the present invention is to change secondary holes into secondary electrons through p-type-doping an absorption layer, where carriers is made run fast because electrons run fast; junction capacitance is reduced with surface area increased by a depletion layer thickened; and fast response speed is obtained with sensitivity effectively improved.

Another purpose of the present invention is to thicken an i-layer, use only one absorption layer and add a DBR layer below an n-type ohmic contact layer for acquiring better effects, where the DBR layer is of indium gallium arsenide phosphide/indium phosphide (InGaAsP/InP) or indium aluminum gallium arsenide/indium aluminum arsenide (InAlGaAs/InAlAs).

To achieve the above purposes, the present invention is a device of avalanche photodetector having a single mesa shape, comprising a p-type ohmic contact layer, a DBR layer, a p-type window layer, a first graded bandgap layer, a p-type absorption layer, a second graded bandgap layer, a field buffer layer, a first p-type field control layer, a second p-type field control layer, a spacer layer, an M-layer, an n-type field control layer, an i-layer and an n-type ohmic contact layer, wherein the p-type ohmic contact layer is a first semiconductor being p⁺-type doped; the DBR layer is a second semiconductor and comprises a plurality of pairs of InGaAsP/InP or InAlGaAs/InAlAs, the p-type window layer is a third semiconductor being p⁺-type doped and interposed between the p-type ohmic contact layer and the DBR layer; the first graded bandgap layer is a fourth semiconductor being p⁺-type doped and interposed between the p-type window layer and the DBR layer; the p-type absorption layer is a fifth semiconductor being graded p-type doped and interposed between the first graded bandgap layer and the DBR layer; the second graded bandgap layer is a sixth semiconductor being undoped and interposed between the p-type absorption layer and the DBR layer; the field buffer layer is a seventh semiconductor being undoped and interposed between the second graded bandgap layer and the DBR layer; the first p-type field control layer is an eighth semiconductor being p-type doped and interposed between the field buffer layer and the DBR layer; the second p-type field control layer is a ninth semiconductor being p-type doped and interposed between the second graded bandgap layer and the DBR layer; the spacer layer is a tenth semiconductor being undoped and interposed between the second p-type field control layer and the DBR layer; the M-layer is an eleventh semiconductor being undoped and interposed between the first p-type field control layer and the DBR layer; the n-type field control layer is a twelfth semiconductor being undoped and interposed between the M-layer and the DBR layer; the i-layer is a thirteenth semiconductor being undoped and interposed between the n-type field control layer and the DBR layer; the n-type ohmic contact layer is a fourteenth semiconductor being n⁺-type doped and interposed between the i-layer and the DBR layer; from top to bottom, the device comprises the p-type ohmic contact layer, the p-type window layer, the first graded bandgap layer, the p-type absorption layer, the second graded bandgap layer, the field buffer layer, the first p-type field control layer, the second p-type field control layer, the spacer layer, the M-layer, the n-type field control layer, the i-layer, the n-type ohmic contact layer and the DBR layer; an epitaxial-layers structure with n-side (the M-layer) down is obtained; a mesa shape is obtained between the second p-type field control layer and the spacer layer; and the mesa shape confines electric field at center of the device. Accordingly, a novel device of avalanche photodetector having a single mesa shape is obtained.

### BRIEF DESCRIPTION OF THE DRAWINGS

The present invention will be better understood from the following detailed description of the preferred embodiment according to the present invention, taken in conjunction with the accompanying drawings, in which

FIG. 1 is the sectional view showing the preferred embodiment according to the present invention;

FIG. 2 is the view showing the two-dimensional distribution of electric field at breakdown;

FIG. 3 is the view showing the one-dimensional distribution of electric field at breakdown;

FIG. 4 is the sectional view showing the state-of-use of the preferred embodiment;

FIG. 5 is the sectional view of InAlAs avalanche photodiode (APD); and

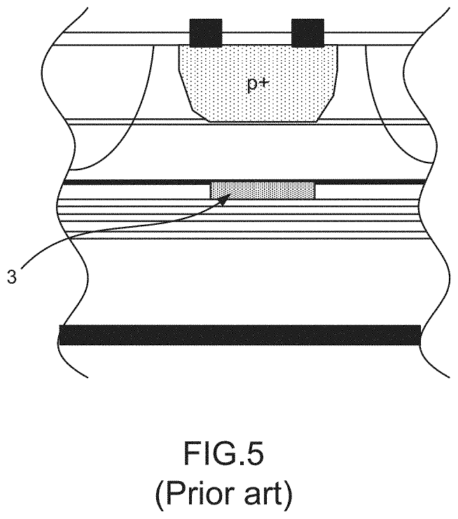

FIG. 6 is the sectional view of another InAlAs APD.

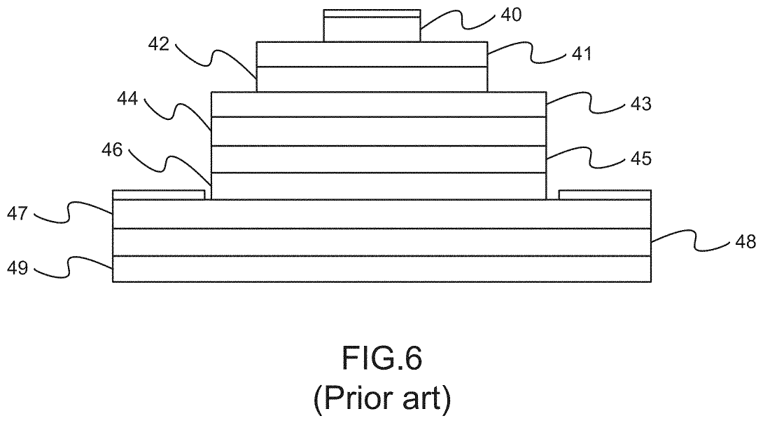

### DESCRIPTION OF THE PREFERRED EMBODIMENT

The following description of the preferred embodiment is provided to understand the features and the structures of the present invention.

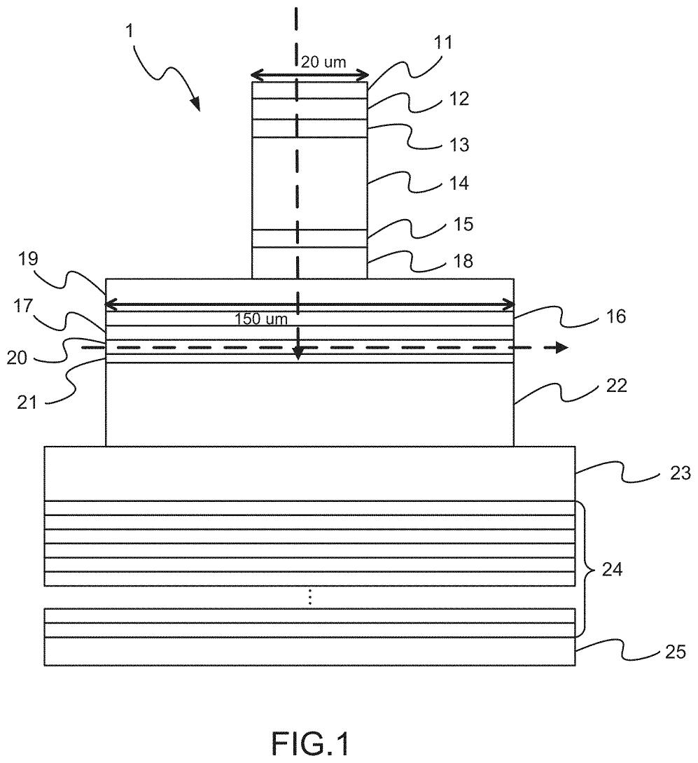

Please refer to FIG. 1 to FIG. 4, which are a sectional view showing a preferred embodiment according to the present invention; a view showing a two-dimensional distribution of electric field at breakdown; a view showing a one-dimensional distribution of electric field at breakdown; a sectional view showing a state-of-use of the preferred embodiment. As shown in the figures, the present invention is a device of avalanche photodetector having a single mesa shape, comprising a p-type ohmic contact layer 11, a p-type window layer 12, a first graded bandgap layer 13, a p-type absorption layer 14, a second graded bandgap layer 15, a field buffer layer 16, a first p-type field control layer 17, a second p-type field control layer 18, a spacer layer 19, a multiplication layer (M-layer) 20, an n-type field control layer 21, an intrinsic layer (i-layer) 22, an n-type ohmic contact layer 23 and a distributed Bragg reflector (DBR) layer 24, from top to bottom. Therein, an epitaxial-layers structure 1 with n-side (the M-layer) down is obtained; a mesa shape is formed between the second p-type field control layer 18 and the spacer layer 19; and the mesa shape confines electric field at center of the device.

The p-type ohmic contact layer 11 is p⁺-type indium gallium arsenide (InGaAs) used as a p-type electrode; the p-type ohmic contact layer may further comprise a p-type conductive metal layer (not shown in the figures), and the p-type ohmic contact layer 11 has a thickness of 1560 nanometers (nm).

The p-type window layer 12 is p⁺-type indium phosphide (InP) or indium aluminum arsenide (InAlAs) interposed between the p-type ohmic contact layer 11 and the DBR layer 24. Therein, the p-type window layer 12 has a thickness of 150˜250 nm.

The first graded bandgap layer 13 is multilayered graded p⁺-type doped InGaAs or InAlAs interposed between the p-type window layer 12 and the DBR layer 24. Therein, the first graded bandgap layer 13 has a thickness of 15˜25 nm.

The p-type absorption layer 14 is graded p-type doped InGaAs interposed between the first graded bandgap layer 13 and the DBR layer 24. Therein, the p-type absorption layer 14 has a thickness thinned to 3600×10⁻¹⁰ meters (Å).

The second graded bandgap layer 15 is undoped InGaAs or InAlAs interposed between the p-type absorption layer 14 and the DBR layer 24. Therein, the second graded bandgap layer 15 has a thickness of 10˜20 nm.

The field buffer layer 16 is undoped InAlAs interposed between the second graded bandgap layer 15 and the DBR layer 24. Therein, the field buffer layer 16 has a thickness of 6.5˜9.5 nm.

The first p-type field control layer 17 is p-type doped InAlAs interposed between the field buffer layer 16 and the DBR layer 24. Therein, the first p-type field control layer 17 has a thickness of 30˜50 nm.

The second p-type field control layer 18 is p-type doped InAlAs interposed between the second graded bandgap layer 15 with the DBR layer 24. Therein, the second p-type field control layer 18 has a thickness of 30˜50 nm.

The spacer layer 19 is an undoped semiconductor interposed between the second p-type field control layer 18 and the DBR layer 24. Therein, the spacer layer 19 has a thickness of 130˜190 nm.

The M-layer 20 is undoped InAlAs interposed between the first p-type field control layer 17 and the DBR layer 24. Therein, the M-layer 20 has a thickness of 176±20 nm.

The n-type field control layer 21 is undoped InAlAs interposed between the M-layer 20 and the DBR layer 24.

The i-layer 22 is undoped InP or InAlAs interposed between the n-type field control layer 21 and the DBR layer 24. Therein, the i-layer 22 has a thickness thickened to 8000 Å.

The n-type ohmic contact layer 23 is n⁺-type doped InP interposed between the i-layer 22 and the DBR layer 24 to be used as an n-type electrode. Furthermore, the n-type ohmic contact layer 23 may further comprise an n-type conductive metal layer (not shown in the figures). Therein, the n-type ohmic contact layer 23 has a thickness of 800˜1200 nm.

The DBR layer 24 is at least five pairs of indium gallium arsenide phosphide/indium phosphide (InGaAsP/InP) or indium aluminum gallium arsenide/indium aluminum arsenide (InAlGaAs/InAlAs).

The epitaxial-layers structure 1 is grown on a semi-insulating or conductive semiconductor substrate 25. The semiconductor substrate 25 is a semiconductor of a compound like gallium arsenide (GaAs), gallium antimonide (GaSb), InP or gallium nitride (GaN); or, of an IV-group element like silicon (Si). Thus, a novel device of avalanche photodetector having a single mesa shape is obtained.

The p-type ohmic contact layer 11 is p⁺-type InₓGa₁₋ₓAs and the p-type absorption layer 14 is graded bandgap InₓGa₁₋ₓAs, where x is 0.53.

The field buffer layer 16 is undoped InₓAl₁₋ₓAs, the first p-type field control layer 17 is p-type InₓAl₁₋ₓAs, and the M-layer 20 is undoped InAl₁₋ₓAs (energy level=1.45 electron volts (eV)), where x is 0.52. Therein, the M-layer 20 is an undoped combination of InₓAl₁₋ₓAs and Inₓ₁Al₁₋ₓ₁As, where x is 0.52 and x1 is a positive number less than 0.52.

The epitaxial-layers structure 1 according to the present invention has a growth method unlimited, which can be any conventional method used under its specific condition. Preferred epitaxial methods for the growth on semiconductor substrate include molecular beam epitaxy (MBE), metalorganic chemical vapor deposition (MOCVD), hydride vapor phase epitaxy (HVPE), etc.

Under the consideration of reliability, the present invention uses an epitaxial-layers structure with n-side down. The strongest electric field of the M-layer 20 is coated in inner bottom layers to avoid surface breakdown. As comparing to a prior art, the present invention thickens the i-layer while the rest layers are moved down. The original second absorption layer is omitted. The first absorption layer (i.e. referred to the p-type absorption layer 14 in the present invention) is slightly thinned. The thickness is reduced from 3800 Å to 3600 Å so that the overall structure becomes shorter. Furthermore, the DBR layer 24 is added below the n-type ohmic contact layer 23; and the DBR layer 24 comprises at least five pairs of InGaAsP/InP or InAlGaAs/InAlAs. Hence, the device obtains better effects. The advantage is as follows: Through p-type-doping the absorption layer, secondary holes are changed into secondary electrons; because the electrons run fast, carriers is also made run fast; and junction capacitance is reduced along with surface area increased by a thicker depletion layer (i.e. the i-layer thickened).

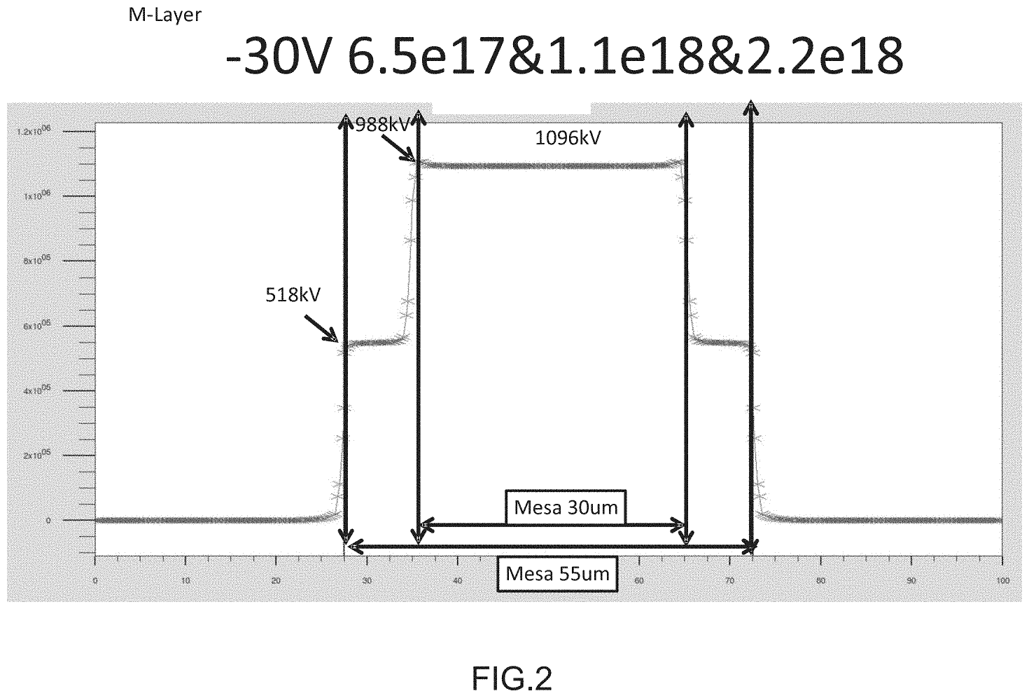

Nevertheless, M-layer has to have a very high electric field at center. The present invention uses a single mesa shape to achieve the effect of limiting the electric field of the M-layer. As shown in FIG. 2, the mesa shape presses the electric field at edge of the M-layer down to 518 kilo-volts (kV). Not only the electric field at the edge of the M-layer has to be pressed down; but also the electric field at center has to be very high. The mesa shape is set at the center with 1096 kv. Thus, the electric field at the edge obtains very high gradience. It is achieved through etching out the mesa shape at a second graded bandgap layer.

As shown in FIG. 2, the limitation of electric field in the x-direction at the center is particularly strong; and the good limitation at the center makes the electric field at the edge small.

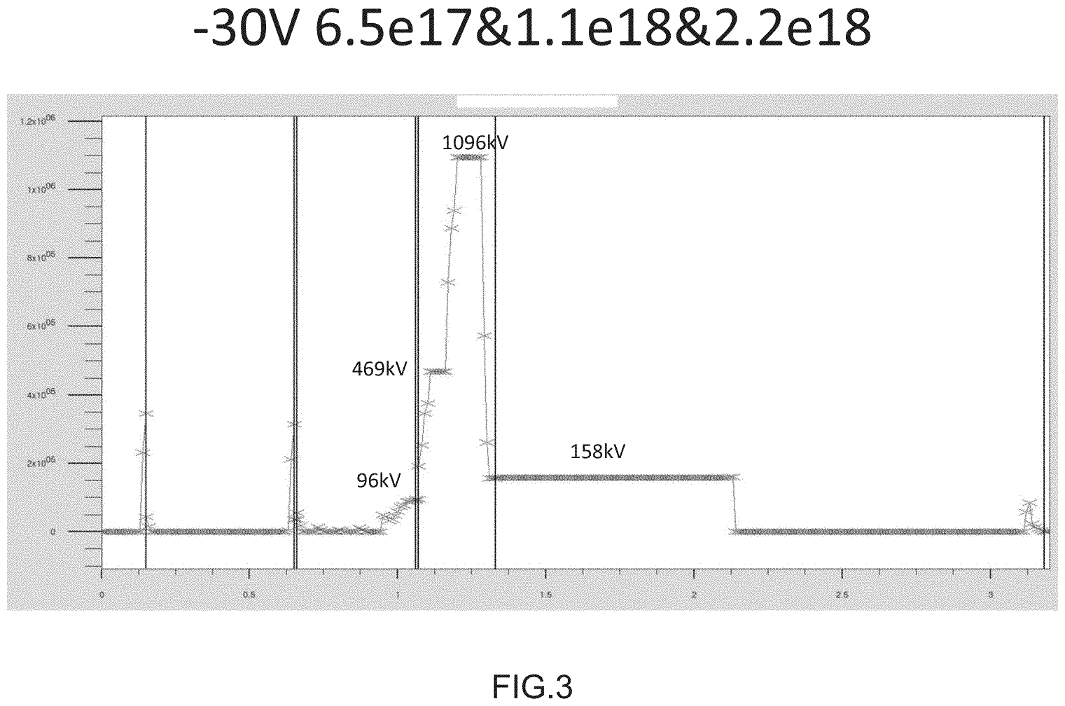

As shown in FIG. 3, the electric field in the y-direction obtains good control, which makes the M-layer obtain a particularly high electric field among all layers and the electric field of the i-layer is very smooth, far below breakdown. In another word, except the particularly high electric field of the M-layer at breakdown, all the other layers in the y-direction do not encounter the breakdowns of electric field. It means that the electric fields of all of the layers are far below breakdown.

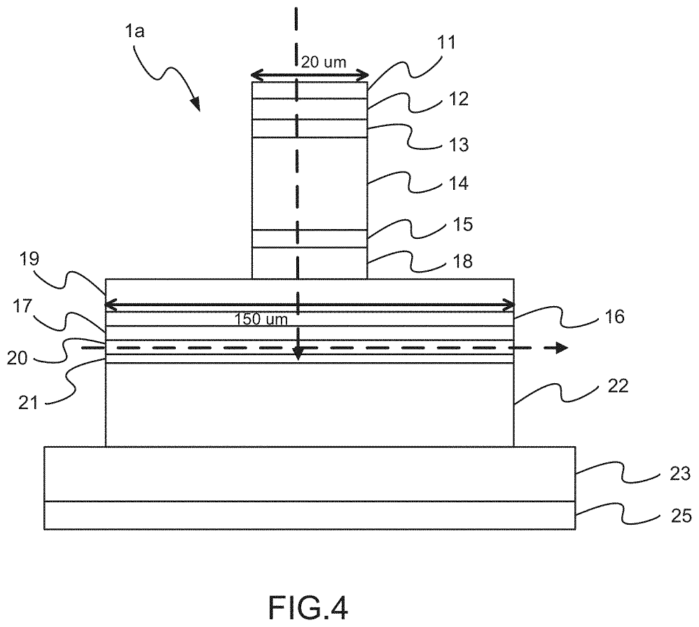

In a state-of-use, the DBR layer can be omitted, as shown in FIG. 4. Therein, an epitaxial-layers structure 1a with n-side down is obtained with a mesa shape formed between the second p-type field control layer 18 and the spacer layer 19 to confine electric field at center of the device.

As is described above, the present invention is a novel APD of InAlAs. An epitaxial-layers structure is used with n-side (M-layer at bottom) down. The strongest electric field of the M-layer is coated in inner bottom layers to avoid surface breakdown. The present invention mainly thickens an i-layer. Only one absorption layer is used. A DBR layer is added below an n-type ohmic contact layer. The DBR layer comprises at least five pairs of InGaAsP/InP or InAlGaAs/InAlAs. A second graded bandgap layer is etched to form a mesa shape, Through the single mesa shape, the M-layer has a high electric field at center along with a low electric field at edge. The electric field of the M-layer is limited. All layers are far below breakdown except the M-layer has a particularly high electric field. Hence, the present invention can be applied to develop high-speed (greater than giga-bits per second (Gbit/sec)) and high linear APDs for high-capacity- and long-distance-transmission Ethernet.

To sum up, the present invention is a device of avalanche photodetector having a single mesa shape, where secondary holes are changed into secondary electrons through p-type-doping an absorption layer; carriers is made run fast because electrons run fast; junction capacitance is reduced with surface area increased by a depletion layer thickened; and fast response speed is obtained with sensitivity effectively improved.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

1. A device of avalanche photodetector having a single mesa shape, comprising
a p-type ohmic contact layer,
wherein said p-type ohmic contact layer is a first semiconductor being p⁺-type doped;
a semiconductor substrate;
a p-type window layer,
wherein said p-type window layer is a third semiconductor being p⁺-type doped and interposed between said p-type ohmic contact layer and said semiconductor substrate;
a first graded bandgap layer,
wherein said first graded bandgap layer is a fourth semiconductor being p⁺-type doped and interposed between said p-type window layer and said semiconductor substrate;
a p-type absorption layer,
wherein said p-type absorption layer is a fifth semiconductor being graded p-type doped and interposed between said first graded bandgap layer and said semiconductor substrate;
a second graded bandgap layer,
wherein said second graded bandgap layer is a sixth semiconductor being undoped and interposed between said p-type absorption layer and said semiconductor substrate;
a field buffer layer,
wherein said field buffer layer is a seventh semiconductor being undoped and interposed between said second graded bandgap layer and said semiconductor substrate;
a first p-type field control layer,
wherein said first p-type field control layer is an eighth semiconductor being p-type doped and interposed between said field buffer layer and said semiconductor substrate;
a second p-type field control layer,
wherein said second p-type field control layer is a ninth semiconductor being p-type doped and interposed between said second graded bandgap layer and said semiconductor substrate;
a spacer layer,
wherein said spacer layer is a tenth semiconductor being undoped and interposed between said second p-type field control layer and said semiconductor substrate;
a multiplication layer (M-layer),
wherein said M-layer is an eleventh semiconductor being undoped and interposed between said first p-type field control layer and said semiconductor substrate;
an n-type field control layer,
wherein said n-type field control layer is a twelfth semiconductor being undoped and interposed between said M-layer and said semiconductor substrate;
an intrinsic layer (i-layer),
wherein said i-layer is a thirteenth semiconductor being undoped and interposed between said n-type field control layer and said semiconductor substrate; and
an n-type ohmic contact layer,
wherein said n-type ohmic contact layer is a fourteenth semiconductor being n⁺-type doped and interposed between said i-layer and said semiconductor substrate;
wherein, from top to bottom, the device comprises said p-type ohmic contact layer, said p-type window layer, said first graded bandgap layer, said p-type absorption layer, said second graded bandgap layer, said field buffer layer, said first p-type field control layer, said second p-type field control layer, said spacer layer, said M-layer, said n-type field control layer, said i-layer, said n-type ohmic contact layer and said semiconductor substrate;
wherein an epitaxial-layers structure with n-side (said M-layer) down is obtained;
wherein a mesa shape is obtained between said second p-type field control layer and said spacer layer; and
wherein said mesa shape confines electric field at center of the device.

2. The device according to claim 1,
wherein said epitaxial-layers structure is grown on said semiconductor substrate selected from a group consisting of a semi-insulating semiconductor substrate and a conductive semiconductor substrate.

3. The device according to claim 1,
wherein said p-type ohmic contact layer is p⁺-type indium gallium arsenide (InGaAs); said p-type window layer is a p⁺-type material selected from a group consisting of p⁺-type indium phosphide (InP) and p⁺-type indium aluminum arsenide (InAlAs); said first graded bandgap layer is p-type InGaAs; said p-type absorption layer is graded p-type doped InGaAs; said second graded bandgap layer is undoped InGaAs; said field buffer layer is undoped InAlAs; said first p-type field control layer is p-type InAlAs; said M-layer is undoped InAlAs; said i-layer is an undoped material selected from a group consisting of undoped InP and undoped InAlAs; and said n-type ohmic contact layer is n⁺-type InP.

4. The device according to claim 1,
wherein said p-type ohmic contact layer is p⁺-type InGaAs; said p-type window layer is a p⁺-type material selected from a group consisting of p⁺-type InP and p⁺-type InAlAs; said first graded bandgap layer is p⁺-type InAlAs; said p-type absorption layer is graded p-type doped InGaAs; said second graded bandgap layer is undoped InAlAs; said field buffer layer is undoped InAlAs; said first p-type field control layer is p-type InAlAs; said M-layer is undoped InAlAs; said i-layer is an undoped material selected from a group consisting of undoped InP and undoped InAlAs; and said n-type ohmic contact layer is n⁺-type InP.

5. The device according to claim 1,
wherein said p-type ohmic contact layer is p⁺-type InₓGa₁₋ₓAs; and said p-type absorption layer is graded bandgap InₓGa₁₋ₓAs and x is 0.53.

6. The device according to claim 1,
wherein said field buffer layer is undoped InₓAl₁₋ₓAs; said first p-type field control layer is p-type InₓAl₁₋ₓAs; and said M-layer is undoped InAl₁₋ₓAs and x is 0.52.

7. The device according to claim 6,
wherein said M-layer is an undoped combination of InₓAl₁₋ₓAs and Inₓ₁Al₁₋ₓ₁As; and x is 0.52 and x1 is a positive number less than 0.52.

8. The device according to claim 1,
wherein said M-layer has a thickness of 176±20 nanometers (nm).

9. (canceled)

10. (canceled)
